(19) United States
(12) Patent Application Publication
(10) Pub. No.: US 2025/0210518 A1
(43) Pub. Date: Jun. 26, 2025

(54) DIRECT BACKSIDE CONTACTS WITH LOCAL INTERCONNECTS

(71) Applicant: International Business Machines Corporation, Armonk, NY (US)

(72) Inventors: Ruilong Xie, Niskayuna, NY (US); Tao Li, Slingerlands, NY (US); Kisik Choi, Watervliet, NY (US); Shay Reboh, Guilderland, NY (US); Julien Frougier, Albany, NY (US)

(21) Appl. No.: 18/392,638

(22) Filed: Dec. 21, 2023

(51) Int. Cl. H01L 23/528; H01L 21/8234; H01L 23/522; H01L 27/088; H01L 29/08; H01L 29/66

(52) U.S. Cl. CPC H01L 23/5283; H01L 23/5226; H10D 62/151; H10D 64/017; H10D 84/0149; H10D 84/038; H10D 84/83

(57) ABSTRACT

Semiconductor devices include transistors in an active layer. Top vias are in electrical contact between top surfaces of the transistors and overlying frontside back-end-of-line (BEOL) layers. A local interconnect is in electrical contact between transistors underneath the transistors. Bottom vias are in electrical contact between bottom surfaces of the transistors and underlying backside BEOL layers.

### BACKGROUND

The present invention generally relates to semiconductor device fabrication and, more particularly, to semiconductor devices having local interconnects between direct backside contacts.

Semiconductor devices that make use of backside power distribution may include direct backside contacts that connect transistors to the backside power. However, dense device layouts can cause congestion at the middle-of-line layer, making it difficult to provide electrical contacts everywhere they are needed.

### SUMMARY

A semiconductor device includes transistors in an active layer. Top vias are in electrical contact between top surfaces of the transistors and overlying frontside back-end-of-line (BEOL) layers. A local interconnect is in electrical contact between transistors underneath the transistors. Bottom vias are in electrical contact between bottom surfaces of the transistors and underlying backside BEOL layers.

A semiconductor device includes transistors in an active layer. Top vias are in electrical contact between top surfaces of the plurality of transistors and overlying frontside BEOL layers. A local interconnect is in electrical contact between transistors underneath the plurality of transistors. A dielectric cap is between the local interconnect and the active layer. Bottom vias are in electrical contact between bottom surfaces of the transistors and underlying backside BEOL layers. The bottom vias each have a first portion with a first width proximate to the active layer and a second portion with a second, greater width, farther away from the active layer.

A semiconductor device includes transistors in an active layer. Top vias are in electrical contact between top surfaces of the transistors and overlying frontside BEOL layers. A local interconnect is in electrical contact between transistors underneath the transistors. Bottom vias are in electrical contact between bottom surfaces of the transistors and underlying backside BEOL layers. The bottom vias each have a continuous width.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a semiconductor device having buried local interconnects that illustrates a set of cross-sectional views, in accordance with an embodiment of the present invention;

FIG. 2 is a set of cross-sectional views of a step in the fabrication of a semiconductor device having buried local interconnects, showing the formation of fin stacks from a stack of semiconductor layers, in accordance with an embodiment of the present invention;

FIG. 3 is a set of cross-sectional views of a step in the fabrication of a semiconductor device having buried local interconnects, showing the formation of buried interconnects, in accordance with an embodiment of the present invention;

FIG. 4 is a set of cross-sectional views of a step in the fabrication of a semiconductor device having buried local interconnects, showing the formation of source/drain structures, in accordance with an embodiment of the present invention;

FIG. 5 is a set of cross-sectional views of a step in the fabrication of a semiconductor device having buried local interconnects, showing the formation of transistor gate stacks, in accordance with an embodiment of the present invention;

FIG. 6 is a set of cross-sectional views of a step in the fabrication of a semiconductor device having buried local interconnects, showing the formation of frontside back-end-of-line (BEOL) layers, in accordance with an embodiment of the present invention;

FIG. 7 is a set of cross-sectional views of a step in the fabrication of a semiconductor device having buried local interconnects, showing the removal of a substrate and the recess of placeholder structures, in accordance with an embodiment of the present invention;

FIG. 8 is a set of cross-sectional views of a step in the fabrication of a semiconductor device having buried local interconnects, showing expansion of vias, in accordance with an embodiment of the present invention;

FIG. 9 is a set of cross-sectional views of a step in the fabrication of a semiconductor device having buried local interconnects, showing the formation of bottom vias, in accordance with an embodiment of the present invention;

FIG. 10 is a set of cross-sectional views of a step in the fabrication of a semiconductor device having buried local interconnects, showing the recess of some bottom vias to form local interconnects, in accordance with an embodiment of the present invention;

FIG. 11 is a set of cross-sectional views of a step in the fabrication of a semiconductor device having buried local interconnects, showing the formation of backside BEOL layers, in accordance with an embodiment of the present invention;

FIG. 12 is a set of cross-sectional views of a step in the fabrication of an alternative semiconductor device having buried local interconnects, showing the formation of transistors without first forming a buried interconnect, in accordance with an embodiment of the present invention;

FIG. 13 is a set of cross-sectional views of a step in the fabrication of an alternative semiconductor device having buried local interconnects, showing the recess of a dielectric to form an opening, in accordance with an embodiment of the present invention;

FIG. 14 is a set of cross-sectional views of a step in the fabrication of an alternative semiconductor device having buried local interconnects, showing the deposition of conductive material in the opening, in accordance with an embodiment of the present invention;

FIG. 15 is a set of cross-sectional views of a step in the fabrication of an alternative semiconductor device having buried local interconnects, showing the recess of the conductive material in the opening to form local interconnects, in accordance with an embodiment of the present invention;

FIG. 16 is a block/flow diagram of a method for fabricating a semiconductor device having buried local interconnects, in accordance with an embodiment of the present invention; and

FIG. 17 is a block/flow diagram of an alternative method for fabricating a semiconductor device having buried local interconnects, in accordance with an embodiment of the present invention.

### DETAILED DESCRIPTION

Local interconnects, for example formed entirely within an interlayer dielectric, can provide connectivity between transistors located close to one another without needing to bring the contact up to the back-end-of-line (BEOL). Using local interconnects frees space at shallower levels, so that other interconnects can reach the conductive lines at the surface of the interlayer dielectric without crowding.

In some embodiments, the local interconnect can be formed beneath the channels of transistors, so that it can connect to later-formed backside contacts. In some embodiments, the local interconnect can be formed along with the backside contacts to form monolithic local contact structures.

Referring now to FIG. 1, a top-down view is shown of a semiconductor device that includes local interconnects. For the sake of illustration, a number of features are omitted. Additionally, it should be understood that the present figures are not drawn to scale, and that the scale may differ from one drawing to the next.

A set of semiconductor channels 102 are shown, having a long axis in the X direction. A set of gates 104 are positioned perpendicularly across the channels 102 in the Y direction. Local interconnects 106 and 108 are shown underneath the channels 102 and the gates 104 in this perspective, providing electrical connectivity between nearby transistors.

A set of cross-sectional planes is shown, including a cross-section X that cuts lengthwise along a channel 102, a cross-section Y1 that cuts perpendicular across a channel 102 in a space between gates 104 and through a first local interconnect 106, and a cross-section Y2 that cuts perpendicular across a channel 102 in a space between gates 104 and through a second local interconnect 108. As will be shown in greater detail below, the first local interconnect 106 may connect two transistors that are in a same plane along the Y axis, while the second local interconnect 108 may connect two transistors that are in different planes along the Y axis.

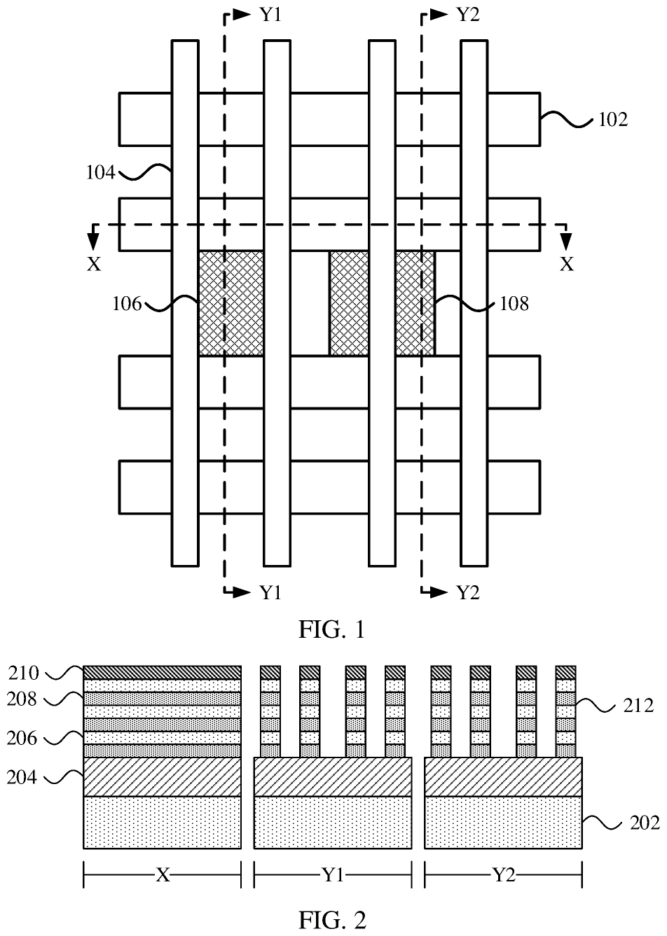

Referring now to FIG. 2, a set of cross-sectional views is shown of a step in the fabrication of a semiconductor device. The process starts with a stack of semiconductor layers on a buried dielectric layer 204 over a semiconductor substrate 202. The stack of semiconductor layers includes channel layers 206 and sacrificial layers 208. The stack may be patterned into fin stacks 212 using a mask 210, followed by an anisotropic etch down to the buried dielectric layer 204. The fin stacks 212 undergo further processing to form an active layer of the semiconductor device.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

The stack of semiconductor layers may be formed, after an initial layer is formed, by successive epitaxial growth processes. The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The channel layers 206 and sacrificial layers 208 may thus be formed from semiconductor materials having compatible crystalline structures, such as silicon for the channel layers 206 and silicon germanium for the sacrificial layers 208. The concentration of germanium in the sacrificial layers 208 may be selected to provide etch selectivity with respect to the channel layers 206, with an exemplary germanium concentration between about 30% and about 60%.

The fin stacks 212 may be formed by a photolithographic process. A pattern may be produced by applying a photoresist to the surface to be etched. The photoresist is exposed to a pattern of radiation and then the pattern is developed into the photoresist utilizing a resist developer. Once the patterning of the photoresist is completed, the sections covered by the photoresist are protected while the exposed regions are removed using a selective etching process that removes the unprotected regions.

A selective anisotropic etch may be used to remove the exposed material from the stack of semiconductor layers. Reactive ion etching (RIE) is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. As used herein, the term “selective” in reference to a material removal process denotes that the rate of material removal for a first material is greater than the rate of removal for at least another material of the structure to which the material removal process is being applied.

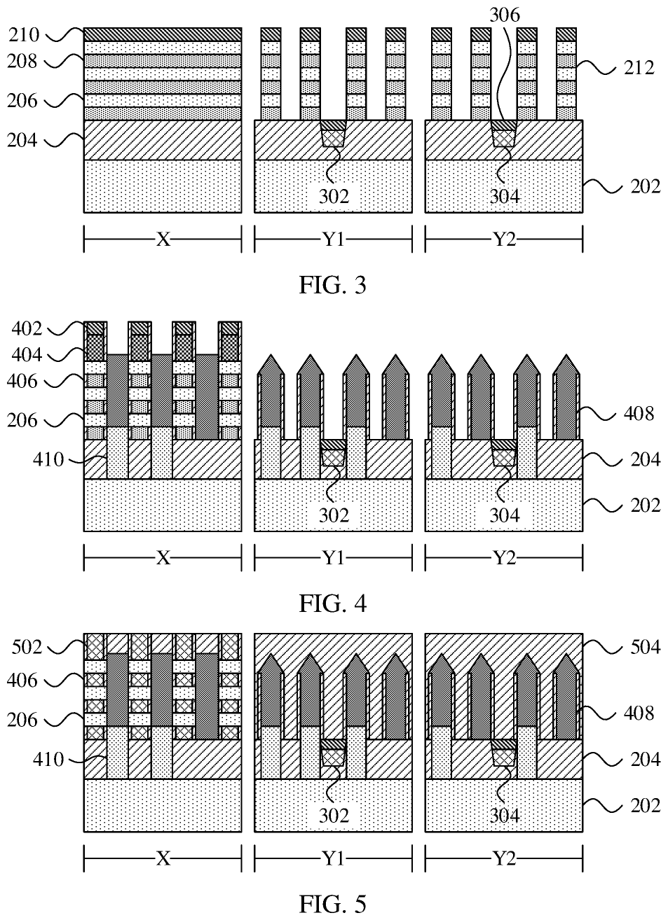

Referring now to FIG. 3, a set of cross-sectional views is shown of a step in the fabrication of a semiconductor device. Buried interconnects are formed between fin stacks 212 in two different planes, including a first buried interconnect 302 and a second buried interconnect 304. Each buried interconnect is covered by a dielectric cap 306. Although an embodiment is shown that includes both buried interconnects 302 and 304, it should be understood that some embodiments may have only one type or the other.

To form the buried interconnects, surrounding structures may be masked and an anisotropic etch may be performed to selectively remove material from the buried dielectric layer 204, forming cavities. The buried interconnects may be formed by depositing a layer of conductive material and then etching it back to below the height of the top surface of the buried dielectric layer 204. The dielectric cap 306 may similarly be formed by depositing any appropriate dielectric material and etching it back to the height of the buried dielectric layer. The dielectric cap may be formed from a dielectric material that is selectively etchable with respect to silicon dioxide, such as SiC, SiOC, AlN, AlOx, and may have a thickness between about 6 nm and about 30 nm.

The buried interconnects may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The dielectric cap 306 may be formed from any appropriate dielectric material, such as SiC, SiOC, AlN, or AlOx.

These structures may be formed by any appropriate deposition process, such as chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 4, a set of cross-sectional views is shown of a step in the fabrication of a semiconductor device. Dummy gates 404 are formed by depositing a layer of any appropriate material, such as polysilicon, and patterning it by forming a mask 402 from, e.g., silicon nitride, followed by a selective anisotropic etch down to the buried dielectric layer 204. The exposed side surfaces of the sacrificial layers 208 may be selectively and isotropically etched to form recesses, which may then be filled by a conformal deposition of dielectric material, such as SiN, SiBCN, SiOCN, SiOC, etc, to form spacers 406. The dielectric material may be different and selectively etchable from the material of the dielectric cap 306. Excess dielectric material from the side spacer deposition may be removed using a selective anisotropic etch.

This process removes the portions of the fin stacks 212 between the dummy gates. A further anisotropic etch may be performed to selectively remove material from the buried dielectric layer 204, forming holes. These holes may be filled with any appropriate placeholder material, such as by growing epitaxial silicon germanium selectively from exposed substrate 202. The resulting placeholder structures 410 penetrate the buried dielectric layer 204 and contact the underlying semiconductor substrate 202.

Source/drain structures 408 may then be grown from the exposed side surfaces of the channel layers 206 and placeholder structures 410. The source/drain structures 408 may be doped in situ during epitaxial deposition as appropriate to the transistor polarity that is being formed. In some cases, some transistors may be formed with an n-type dopant in the associated source/drain structures 408, while other transistors may be formed with a p-type dopant in the respective source/drain structures 408.

Referring now to FIG. 5, a set of cross-sectional views is shown of a step in the fabrication of a semiconductor device. Dielectric material is deposited using any appropriate deposition process and material, such as a flowable CVD of silicon dioxide. A chemical mechanical planarization (CMP) is then performed, polishing the dielectric material and other structures down until the dummy gates 404 are exposed. This CMP leaves interlayer dielectric 504.

CMP is performed using, e.g., a chemical or granular slurry and mechanical force to gradually remove upper layers of the device. The slurry may be formulated to be unable to dissolve, for example, the dummy gate material material, resulting in the CMP process's inability to proceed any farther than that layer.

The dummy gates 404 is then etched away using any appropriate selective etching process. The removal of the dummy gates 404 exposes sidewalls of the semiconductor layers, so that the sacrificial layers 208 may be isotropically and selectively etched away, leaving the channel layers 206 suspended. A gate stack 502 may then be deposited on and around the channel layers 206. The gate stack 502 may include a gate dielectric, a gate conductor, and optionally a work function metal layer.

The gate dielectric may be formed from a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum. The gate conductor may be formed from any appropriate conductive material, such as work function metals, followed by conductive metal fill materials.

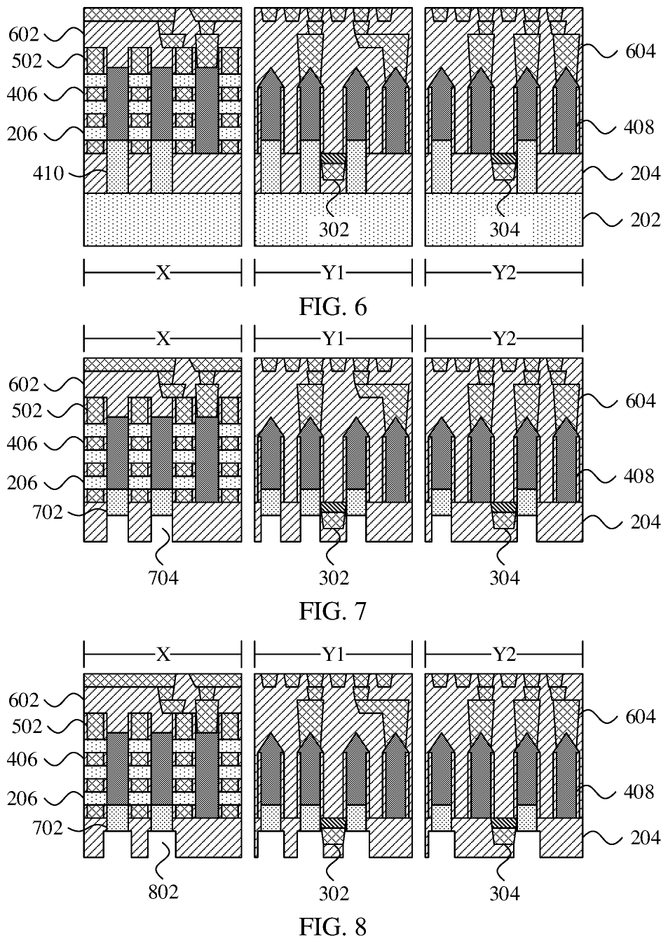

Referring now to FIG. 6, a set of cross-sectional views is shown of a step in the fabrication of a semiconductor device. Additional dielectric material is deposited in layers, extending the interlayer dielectric 602. At each layer of additional dielectric material, top vias 604 may be formed by etching into the dielectric material and depositing conductive material, followed by a CMP to polish the top surface flat.

The interconnects may include middle-of-line contacts that reach to the gate stack 502 or the source/drain structures 408. In some cases, the middle-of-line contact may extend horizontally over another structure. BEOL layers may further be formed above the middle-of-line contacts. Because some structures will be connected by local interconnects and backside contacts, the density of frontside middle of line interconnects may be reduced, which reduces the likelihood of inadvertent short-circuits and tip-to-tip effects.

At this stage, a carrier wafer (not shown) may be attached to the front side of the wafer. The carrier wafer may be attached using a layer of bonding oxide. The entire wafer may then be flipped upside down for further processing on the back side of the wafer.

Referring now to FIG. 7, a set of cross-sectional views is shown of a step in the fabrication of a semiconductor device. The wafer is flipped. The semiconductor substrate 202 is removed, for example using a selective etch or a CMP process that stops on the buried dielectric layer 204. The placeholder structures 410 are recessed to form recessed placeholders 702 to at least the level of the buried interconnects 302/304. The recess may be performed using any appropriate selective etch. Recessing the placeholder structures 410 exposes vias 704 within the buried dielectric layer 204.

Referring now to FIG. 8, a set of cross-sectional views is shown of a step in the fabrication of a semiconductor device. A selective isotropic etch is used to remove material from the sidewalls of the vias 704, widening them into expanded vias 802. In some locations, the expanded vias 802 expose a sidewall buried interconnects 302/304.

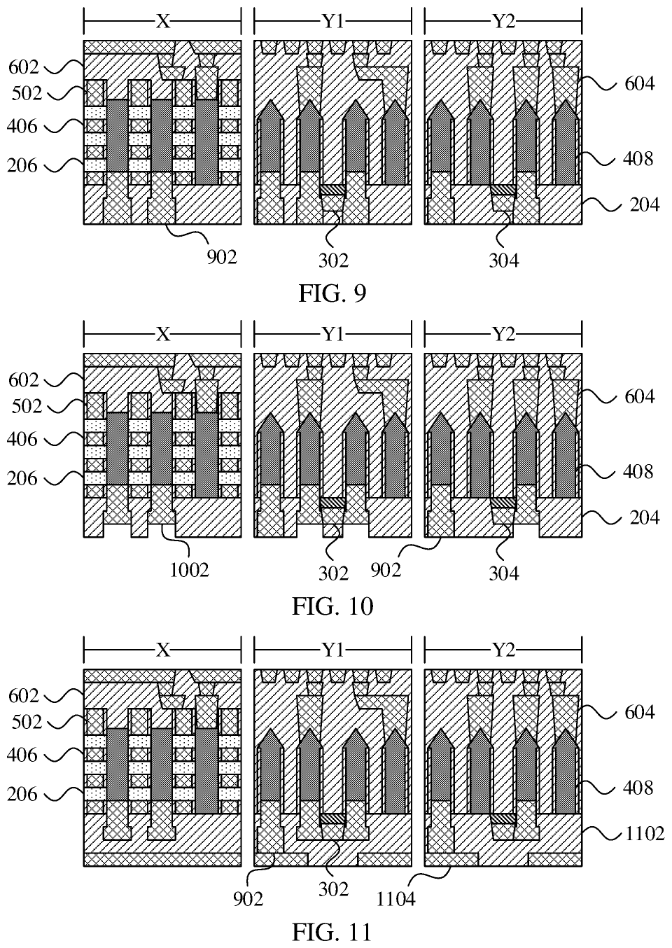

Referring now to FIG. 9, a set of cross-sectional views is shown of a step in the fabrication of a semiconductor device. Remaining placeholder structures 410 are removed. The expanded vias 802 are filled with conductive material, which may be deposited using any appropriate deposition process. The conductive material may then be polished to the level of the buried dielectric layer 204 to form conductive bottom vias 902. In areas where the expanded vias 802 exposed the buried interconnects 302/304, the corresponding conductive bottom vias 902 make electrical contact with the buried interconnects 302/304, creating a local interconnect. Because the expanded vias 802 have regions of different widths, the bottom vias 902 will have a first portion with a first width near the active layer and a second portion with a second, greater width, farther away from the active layer. The widths are discontinuous, with the bottom vias 902 having a stepped profile, instead of a consistent or continuously changing width.

Referring now to FIG. 10, a set of cross-sectional views is shown of a step in the fabrication of a semiconductor device. Those conductive bottom vias 902 which contact the buried interconnects 302/304 are recessed to a depth below the surface of the buried dielectric layer 204, forming local vias 1002. Contact between the local vias 1002 and the buried interconnects 302/304 is maintained, so that the electrical path between associated transistors is maintained. To selectively recess the local vias 1002, a mask may be formed using any appropriate photolithographic process, for example creating a pattern from an organic planarizing layer and then etching the exposed conductive material back with a selective etch. The mask may then be removed.

In such embodiments, a local interconnect may incorporate the buried interconnects 302/304 and local vias 1002. Because the local vias 1002 have regions with different widths along their lengths, the local interconnect in such embodiments will have a horizontal part that extends laterally past vertical parts of the local vias 1002.

Referring now to FIG. 11, a set of cross-sectional views is shown of a step in the fabrication of a semiconductor device. Additional dielectric material may be added in stages to form backside interlayer dielectric 1102. Backside BEOL layers 1104 may be formed, with conductive lines making contact with those conductive vias which reach the surface of the backside interlayer dielectric 1102. The buried interconnects 302/304 are covered by the backside interlayer dielectric 1102, so that they are electrically isolated from the bottom vias 902.

Referring now to FIG. 12, a set of cross-sectional views is shown of a step in an alternative process flow in the fabrication of a semiconductor device. In some embodiments, the buried interconnects 302/304 may not be formed at an early stage. Fabrication of the transistors, frontside top vias 604, and frontside interlayer dielectric 602 may proceed as described above and the buried interconnects may instead be formed backside processing stages.

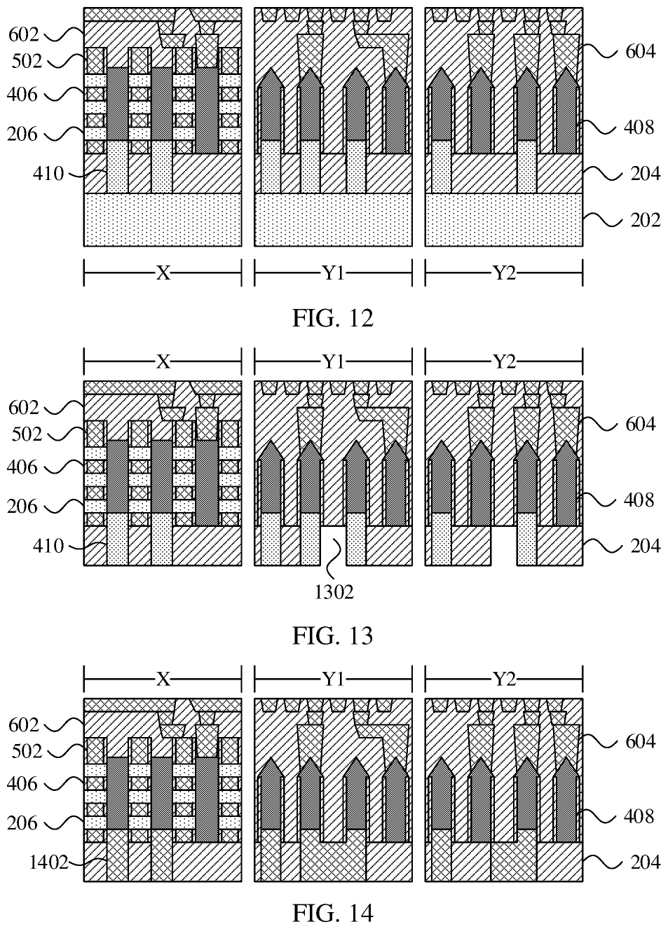

Referring now to FIG. 13, a set of cross-sectional views is shown of a step in an alternative process flow in the fabrication of a semiconductor device. A region of the buried dielectric layer 204 abutting one or more of the placeholder structures 410 is etched away, leaving opening 1302.

Referring now to FIG. 14, a set of cross-sectional views is shown of a step in an alternative process flow in the fabrication of a semiconductor device. The placeholder structures 410 are selectively etched away and the openings in the buried dielectric layer 204 are filled with conductive material to form bottom vias 1402 that contact the source/drain structures 408. The conductive material may be deposited by any appropriate deposition process, and excess material may be removed with a CMP process that stops on the buried dielectric layer 204. The bottom vias 1402 may have a consistent or continuously changing width along their lengths.

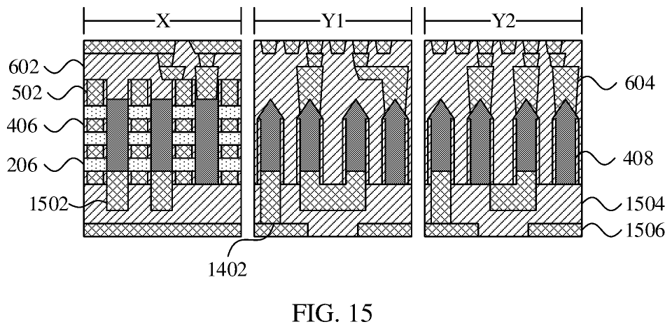

Referring now to FIG. 15, a set of cross-sectional views is shown of a step in an alternative process flow in the fabrication of a semiconductor device. A mask may be used to define some of the bottom vias 1402 that are to be etched back, forming local interconnect 1502. As above, additional material may be added in stages to form backside interlayer dielectric 1504, and backside BEOL layers 1506 may be formed, with conductive lines making contact with those bottom vias 1402 which reach the surface of the backside interlayer dielectric 1504.

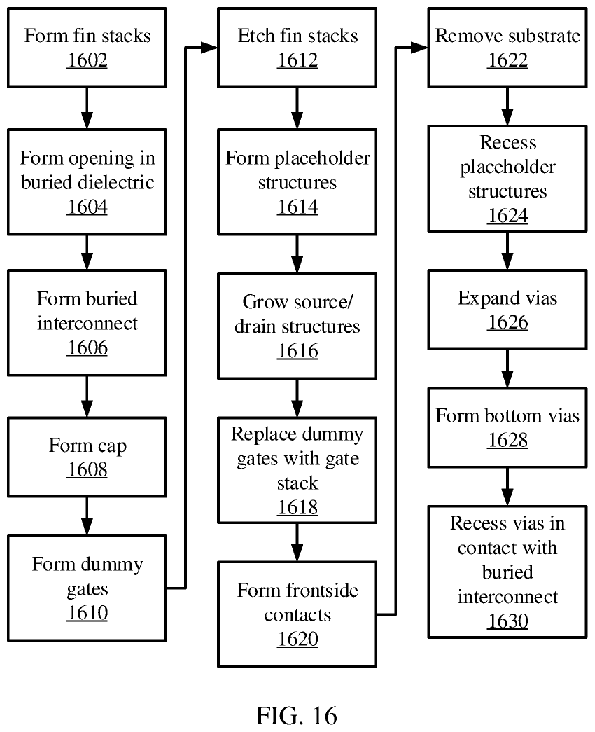

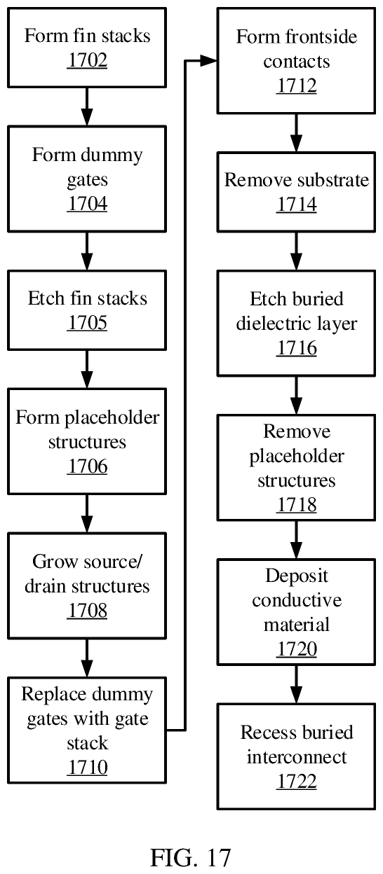

Referring now to FIG. 16, a first embodiment of a method of forming a semiconductor device with local interconnects is shown. Block 1602 forms fin stacks from a stack of semiconductor layers that includes channel layers 206 and sacrificial layers 208. The fin stacks 212 may be formed by forming a mask 210 using a photolithographic process and using a selective anisotropic etch to remove exposed semiconductor material down to the buried dielectric layer 204.

Block 1604 forms an opening in the buried dielectric layer 204. The opening may be formed by masking other regions of the device and performing a timed anisotropic etch to a predetermined depth. Block 1606 forms buried interconnect 302/304 by, e.g., depositing conductive material using any appropriate deposition process and then etching the conductive material back to a predetermined depth. Block 1608 forms dielectric cap 306 over the buried interconnect 302/304 by, e.g., depositing dielectric material using any appropriate deposition process and then etching the dielectric material back to at least the top surface of the buried dielectric layer 204.

Block 1610 forms dummy gates 404 over the fin stacks 212, for example by depositing a layer of dummy gate material, forming a mask 402 using a photolithographic process, and etching down into the dummy gate material using a selective anisotropic etch. Block 1612 then further etches the fin stacks 212 using the dummy gate 404 as a mask. The sacrificial layers 208 may be recessed and spacers 406 may be formed from dielectric material. Openings may be etched into the buried dielectric layer 204 using a selective anisotropic etch, and the opening may be filled with a placeholder material to form placeholder structures 410 by block 1614. Block 1616 may form source/drain structures 408 by epitaxial deposition from exposed side surfaces of the channel layers 206.

Block 1618 replaces the dummy gate 404 with gate stack 502, for example with a selective etch of the dummy gate material followed by a conformal deposition of a gate dielectric and a gate conductor. Block 1620 forms top vias 604 to the transistors, for example including contacts that contact the gates and source/drain regions of the transistors. The formation of the top vias 604 may include patterning a dielectric material in multiple layers, so that a given interconnect to a first transistor may extend laterally over other components of second transistor. Block 1620 may further include formation of frontside BEOL layers to provide signal and power connections to the transistors.

At this stage, a carrier wafer may be bonded to the front side of the wafer so that the wafer may be flipped over and so that further processing may be performed on the back side. Block 1622 removes the semiconductor substrate 202, for example using a selective etch or CMP process that stops on the buried dielectric layer 204. Block 1624 recesses the placeholder structures 410 to form recessed placeholders 702 in vias 704. Block 1626 then uses a selective isotropic etch of the dielectric material of the buried dielectric layer 204 to widen the vias 704, forming expanded vias 802 and exposing a side surface of the buried interconnect 302/304.

Block 1628 fills the expanded vias 802 with conductive material and polishes excess material away with a CMP process, forming bottom vias 902. Block 1630 then forms a mask over those bottom vias 902 which will make contact with backside BEOL layers and recesses the vias which are in contact with buried interconnect 302/304. Additional processing steps may be performed at this time, forming a backside interlayer dielectric 1102 and backside BEOL layers 1104 to make contact with the bottom vias 902.

Referring now to FIG. 17, a second embodiment of a method of forming a semiconductor device with local interconnects is shown. As described above, block 1702 forms fin stacks from a stack of semiconductor layers that includes channel layers 206 and sacrificial layers 208. The fin stacks 212 may be formed by forming a mask 210 using a photolithographic process and using a selective anisotropic etch to remove exposed semiconductor material down to the buried dielectric layer 204.

Rather than forming the buried interconnect during frontside processing, processing continues to the formation of dummy gates over the fin stacks in block 1704, for example by depositing a layer of dummy gate material, forming a mask using a photolithographic process, and etching down into the dummy gate material using a selective anisotropic etch. Block 1705 then further etches the fin stacks using the dummy gate as a mask. The sacrificial layers 208 may be recessed and spacers may be formed from dielectric material. Openings may be etched into the buried dielectric layer 204 using a selective anisotropic etch, and the opening may be filled with a placeholder material to form placeholder structures 410 by block 1706. Block 1708 may form source/drain structures 408 by epitaxial deposition from exposed side surfaces of the channel layers 206.

Block 1710 replaces the dummy gate with gate stack 502, for example with a selective etch of the dummy gate material followed by a conformal deposition of a gate dielectric and a gate conductor. Block 1712 forms top vias 604 to the transistors, for example including contacts that contact the gates and source/drain regions of the transistors. The formation of the top vias 604 may include patterning a dielectric material in multiple layers, so that a given interconnect to a first transistor may extend laterally over other components of second transistor. Block 1712 may further include formation of frontside BEOL layers to provide signal and power connections to the transistors.

At this stage, a carrier wafer may be bonded to the front side of the wafer so that the wafer may be flipped over and so that further processing may be performed on the back side. Block 1714 removes the semiconductor substrate 202, for example using a selective etch or CMP process that stops on the buried dielectric layer 204. Block 1716 masks and etches the buried dielectric layer 204 to form opening 1302 adjacent to one or more placeholder structures 410.

Block 1718 etches away the placeholder structures 410 using any appropriately selective etch process. Block 1720 then deposits conductive material and polishes away any excess using a CMP process to form bottom vias 1402. Block 1722 masks those bottom vias 1402 which will make contact with the backside BEOL layers 1506. Additional processing steps may be performed at this time, forming a backside interlayer dielectric 1504 and backside BEOL layers 1506 to make contact with the bottom vias 1402.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of direct buried contacts with local interconnects (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a plurality of transistors in an active layer;
a plurality of top vias in electrical contact between top surfaces of the plurality of transistors and overlying frontside back-end-of-line (BEOL) layers;
a local interconnect in electrical contact between transistors of the plurality of transistors underneath the plurality of transistors; and
a plurality of bottom vias in electrical contact between bottom surfaces of the plurality of transistors and underlying backside BEOL layers.

2. The semiconductor device of claim 1, wherein the bottom vias are electrically isolated from the local interconnect.

3. The semiconductor device of claim 1, further comprising a dielectric cap formed between the local interconnect and the active layer.

4. The semiconductor device of claim 3, further comprising a backside interlayer dielectric between the backside BEOL layers and the local interconnect, formed from a dielectric material different from material of the dielectric cap.

5. The semiconductor device of claim 1, wherein a first via of the plurality of top vias, connected to a first transistor of the plurality of transistors, includes a horizontal part that extends laterally over a second transistor of the plurality of transistors.

6. The semiconductor device of claim 5, wherein the first via is in electrical contact with a source/drain structure of the first transistor and the local interconnect is in electrical contact with a source/drain of the second transistor.

7. The semiconductor device of claim 5, wherein the first via is in electrical contact with a gate of the first transistor and the local interconnect is in electrical contact with a source/drain structure of the second transistor.

8. The semiconductor device of claim 1, wherein the bottom vias have a first portion with a first width proximate to the active layer and a second portion with a second, greater width, farther away from the active layer.

9. The semiconductor device of claim 1, wherein the bottom vias have a continuous width.

10. A semiconductor device, comprising:
a plurality of transistors in an active layer;
a plurality of top vias in electrical contact between top surfaces of the plurality of transistors and overlying frontside back-end-of-line (BEOL) layers;
a local interconnect in electrical contact between transistors of the plurality of transistors underneath the plurality of transistors;
a dielectric cap between the local interconnect and the active layer; and
a plurality of bottom vias in electrical contact between bottom surfaces of the plurality of transistors and underlying backside BEOL layers, the bottom vias each having a first portion with a first width proximate to the active layer and a second portion with a second, greater width, farther away from the active layer.

11. The semiconductor device of claim 10, wherein the bottom vias are electrically isolated from the local interconnect.

12. The semiconductor device of claim 10, further comprising a backside interlayer dielectric between the backside BEOL layers and the local interconnect, formed from a dielectric material different from material of the dielectric cap.

13. The semiconductor device of claim 10, wherein a first via of the plurality of top vias, connected to a first transistor of the plurality of transistors, includes a horizontal part that extends laterally over a second transistor of the plurality of transistors.

14. The semiconductor device of claim 13, wherein the first via is in electrical contact with a source/drain structure of the first transistor and the local interconnect is in electrical contact with a source/drain of the second transistor.

15. The semiconductor device of claim 13, wherein the first via is in electrical contact with a gate of the first transistor and the local interconnect is in electrical contact with a source/drain structure of the second transistor.

16. A semiconductor device, comprising:
a plurality of transistors in an active layer;
a plurality of top vias in electrical contact between top surfaces of the plurality of transistors and overlying frontside back-end-of-line (BEOL) layers;
a local interconnect in electrical contact between transistors of the plurality of transistors underneath the plurality of transistors; and
a plurality of bottom vias in electrical contact between bottom surfaces of the plurality of transistors and underlying backside BEOL layers, the bottom vias each having a continuous width.

17. The semiconductor device of claim 16, further comprising a backside interlayer dielectric between the backside BEOL layers and the local interconnect.

18. The semiconductor device of claim 16, wherein a first via of the plurality of top vias, connected to a first transistor of the plurality of transistors, includes a horizontal part that extends laterally over a second transistor of the plurality of transistors.

19. The semiconductor device of claim 18, wherein the first via is in electrical contact with a source/drain structure of the first transistor and the local interconnect is in electrical contact with a source/drain of the second transistor.

20. The semiconductor device of claim 18, wherein the first via is in electrical contact with a gate of the first transistor and the local interconnect is in electrical contact with a source/drain structure of the second transistor.
